(19) United States
(12) Patent Application Publication
(10) Pub. No.: US 2007/0080629 A1
(43) Pub. Date: Apr. 12, 2007

(54) Double-Sided Organic Light-Emitting Diode Display

(75) Inventor: Chung-Wen Ko, Sijhih City, Taipei County (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU OPTRONICS CORPORATION, Hsin-Chu (TW)

(21) Appl. No.: 11/459,383

(22) Filed: Jul. 24, 2006

(30) Foreign Application Priority Data
Oct. 11, 2005 (TW) 94135382

(51) Int. Cl. H01J 1/62

(52) U.S. Cl. 313/504; 313/498; 313/512; 313/506

(57) ABSTRACT

A double-sided organic light-emitting display includes at least one organic light-emitting display of top emission type stacked over another organic light-emitting display.

### RELATED APPLICATIONS

The present application is based on, and claims priority from, Taiwan Patent Application Serial Number 94135382, filed Oct. 11, 2005, the disclosure of which is hereby incorporated by reference herein in its entirety.

### BACKGROUND

1. Field of Invention

The present invention relates to a double-sided display. More particularly, the present invention relates to a double-sided organic light-emitting diode (OLED) display.

2. Description of Related Art

Since the functions of mobile electronic products have been diversified, a need for double-sided display is getting increased. Especially for mobile phone, personal digital assistant (PDA), or notebook, these products usually require double-sided display to increase functional flexibilities. Since OLED display has distinguishing characteristics such as light, high brightness, low power consumption, wide view angle, self-luminescence, fast response, simple fabrication process, and low cost. All of these features lead OLED display to be of great application potential. Therefore, OLED display are possibly the next generation planar display and light source.

A conventional double-sided OLED display is made by assembling two independent OLED displays of bottom-emission type. Since the thickness of this type of double-sided OLED display is thicker, drawbacks of additional components and higher cost are expected.

Another conventional double-sided OLED display is made by assembling two substrates with their bottom-emission OLED array face to face, and a sealant is used to seal bottom-emission OLED arrays between the two substrates. This type of double-sided OLED display can save two sealing covers for the two OLED arrays, hence the thickness of this double-sided OLED display can be reduced. However, this type of double-sided OLED display is only suitable for bottom-emission OLEDs. When top-emission OLEDs are considered to fabricate an active matrix type OLED array having a more complicated circuit design, this idea of double-sided OLED display cannot be used.

Yet another conventional double-sided OLED display is made by fabricating a top-emission OLED array and a bottom-emission OLED array on different areas of a single substrate. Although only one substrate is used in the double-sided OLED display, the display area of each display array is usually too small for mobile electronic products of small size. Therefore, the resolution and quality of the pictures displayed on this type of double-sided OLED display are usually lower.

### SUMMARY

In one aspect, the present invention provides a double-sided OLED display using at least one top-emission array to provide frames with high quality and high resolution.

In accordance with the foregoing and other aspects of the present invention, a double-sided OLED display having a first and a second OLED panels is provided. The first OLED panel comprises a first substrate and a first OLED array of top-emission type on the top surface of the first substrate, a first sealant sealing the first OLED array. The second OLED panel comprises a second substrate and a second OLED array of top-emission type on the top surface of the second substrate, a second sealant sealing the first OLED array. The bottom surface of the first substrate is attached to the bottom surface of the second substrate.

According to a preferred embodiment, the first and the second sealants can be glass covers or passivation layers. The material of the passivation layers is, for example, silicon nitride, silicon oxide, silicon oxynitride, or a waterproof organic polymer.

In accordance with the foregoing and other aspects of the present invention, another double-sided OLED display is provided. The structure of the double-sided OLED display comprises a first substrate, a first OLED array of bottom-emission type, a second substrate sealing the first OLED array, a second OLED array of top-emission type, and a sealant sealing the second OLED array.

According to a preferred embodiment, the sealant can be a glass cover or a passivation layer. The material of the passivation layer is, for example, silicon nitride, silicon oxide, silicon oxynitride, or a waterproof organic polymer.

As embodied and broadly described herein, the invention provides a double-sided OLED display using at least one OLED panel of top-emission type to stack over another OLED panel. Hence, the total area of the double-sided OLED display can be used as the display area to increase the quality and resolution of displayed frames. Moreover, since one OLED panel of top-emission type is adopted, the active OLED matrix technology can be used to further increase the quality of the displayed frames without sacrificing the opening ratio.

It is to be understood that both the foregoing general description and the following detailed description are made by use of examples and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A is a cross-sectional diagram showing a double-sided OLED display according to a preferred embodiment of this invention;

FIG. 1B is a cross-sectional diagram showing a double-sided OLED display according to another preferred embodiment of this invention;

FIG. 2A is a cross-sectional diagram showing a double-sided OLED display according to yet another preferred embodiment of this invention; and

FIG. 2B is a cross-sectional diagram showing a double-sided OLED display according to yet another preferred embodiment of this invention.

### DESCRIPTION OF THE PREFERRED EMBODIMENTS

This invention provides a double-sided OLED display made by stacking an OLED panel of top-emission type over another OLED panel to increase the quality and resolution of displayed frames. Reference will now be made in detail to the present preferred embodiments of the invention, examples of which are illustrated in the accompanying drawings. Wherever possible, the same reference numbers are used in the drawings and the description to refer to the same or like parts.

Generally, an OLED is made by stacking layers including an anode, an organic emission layer, and a cathode on a substrate. A bottom-emission OLED emits light outwards from the substrate side, and the bottom electrode is transparent. A top-emission OLED emits light outwards from the top electrode side, and the top electrode is transparent. When the top electrode is cathode, the bottom electrode is anode, and vice versa.

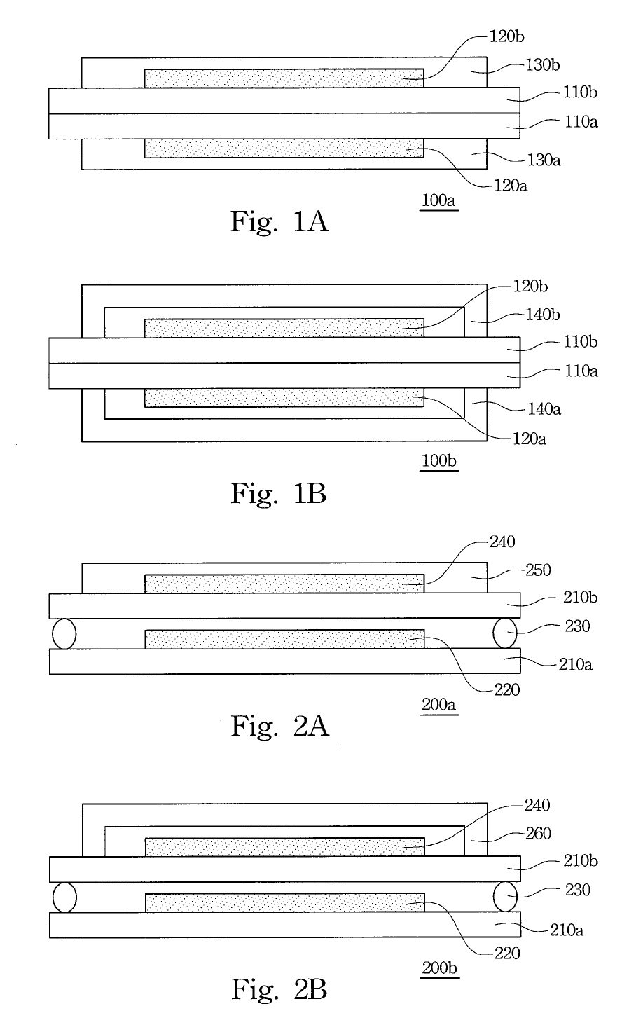

FIG. 1A is a cross-sectional diagram showing a double-sided OLED display according to a preferred embodiment of this invention. In FIG. 1A, a double-sided OLED display 100a comprises two OLED panels of top-emission types. The first OLED panel is made by assembling a substrate 110a, a top-emission OLED array 120a, and a passivation layer 130a. The second OLED panel is made by assembling a substrate 110b, a top-emission OLED array 120b, and a passivation layer 130b. The two OLED panels are attached to each other back-to-back to form the double-sided OLED display 100a.

The passivation layers 130a and 130b are used to seal the OLED array 120a and 120b, respectively, to prevent OLED array 120a and 120b from being damaged by the ambient moisture. Hence, the material of the passivation layers 130a and 130b can be silicon nitride, silicon oxide, silicon oxynitride or other waterproof organic polymer.

FIG. 1B is a cross-sectional diagram showing a double-sided OLED display according to another preferred embodiment of this invention. The passivation layers 130a and 130b in FIG. 1A are replaced by glass covers 140a and 140b in FIG. 1B to seal the OLED array 120a and 120b. Although the structure of the glass covers 140a and 140b are different from the passivation layers 130a and 130b, their functions are the same.

FIG. 2A is a cross-sectional diagram showing a double-sided OLED display according to yet another preferred embodiment of this invention. In FIG. 2A, the double-sided OLED display is made by assembling by stacking a top-emission OLED panel on a bottom-emission OLED panel. The bottom-emission OLED panel is made by assembling a bottom substrate 210a, a bottom-emission OLED array 220, a top substrate 210b and a sealant 230. The top-emission OLED panel is made by assembling a top substrate 210b, a top-emission OLED array 240 and a passivation layer 250. Hence, the top substrate 210b is shared by the top-emission OLED panel and the bottom-emission OLED panel.

The function of the passivation layer 250 in FIG. 2A is the same as the function of the passivation layers 130a and 130b in FIG. 1A. The passivation layer 250 is used to prevent the top-emission OLED array 240 from being damaged by ambient moisture. Hence, the material of the passivation layers 250 can be silicon nitride, silicon oxide, silicon oxynitride or other waterproof organic polymer. The sealant 230 is responsible for filling the interstice between the top substrate 210b and the bottom substrate 210a to prevent the bottom-emission layer 220 from moisture.

FIG. 2B is a cross-sectional diagram showing a double-sided OLED display according to yet another preferred embodiment of this invention. The passivation layer 250 in FIG. 2A is replaced by a glass cover 260 in FIG. 2B to seal the top-emission OLED array 240. Although the structure of the glass cover 260 is different from the passivation layer 250, their functions are the same.

Accordingly, at least a top-emission OLED panel is used to stack on another OLED panel in the preferred embodiments of this invention. Hence, the whole area of the double-sided OLED display can be used as the display area to increase the quality and resolution of the displayed frames. Moreover, since one OLED panel of top-emission type is adopted, the active OLED matrix technology can be used to further increase the quality of the displayed frames without sacrificing the opening ratio.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A double-sided organic light-emitting diode (OLED) display, comprising:
a first substrate;
a first OLED array of top-emission type disposed on a top surface of the first substrate;
a first sealant on the first OLED array;
a second substrate attached to the first substrate;
a second OLED array of top-emission type disposed on a surface of the second substrate; and
a second sealant on the second OLED array to seal the second OLED array.

2. The double-sided OLED display of claim 1, wherein the first sealant and the second sealant comprise a passivation layer.

3. The double-sided OLED display of claim 2, wherein the passivation layer is made of a silicon nitride, silicon oxide, silicon oxynitride, or a waterproof organic polymer.

4. A double-sided organic light-emitting diode (OLED) display, comprising:
a first substrate;
a first OLED array of top-emission type disposed on a top surface of the first substrate;
a first glass cover on the first OLED array;
a second substrate attached to the first substrate;
a second OLED array of top-emission type disposed on a surface of the second substrate; and
a second glass cover on the second OLED array to seal the second OLED array.

5. A double-sided organic light-emitting diode (OLED) display, comprising:
a first substrate;
a first OLED array of bottom-emission type disposed on the first substrate;
a second substrate on the first OLED array;
a second OLED array of top-emission type disposed on the second substrate; and
a first sealant on the second OLED array to seal the second OLED array.

6. The double-sided OLED display of claim 5, wherein the first sealant comprises a passivation layer.

7. The double-sided OLED display of claim 6, wherein the passivation layer is made of a silicon nitride, silicon oxide, silicon oxynitride, or a waterproof organic polymer.

8. The double-sided OLED display of claim 5, further comprising a second sealant between the margins of the first and the second substrates.

9. A double-sided organic light-emitting diode (OLED) display, comprising:
a first substrate;
a first OLED array of bottom-emission type disposed on the first substrate;
a second substrate on the first OLED array;
a second OLED array of top-emission type disposed on the second substrate; and
a first glass cover on the second OLED array to seal the second OLED array.
